(19) United States
(12) Patent Application Publication
(10) Pub. No.: US 2021/0307200 A1
(43) Pub. Date: Sep. 30, 2021

(54) Cooling Unit

(71) Applicant: Brian S. Kim, Rancho Palos Verdes, CA (US)

(72) Inventor: Brian S. Kim, Rancho Palos Verdes, CA (US)

(21) Appl. No.: 16/830,118

(22) Filed: Mar. 25, 2020

(51) Int. Cl. H05K 7/20; F25D 17/06; F25D 17/02; F25D 7/00

(52) U.S. Cl. CPC H05K 7/20327; F25D 17/067; F25D 2317/0681; F25D 7/00; F25D 17/02

(57) ABSTRACT

A cooling unit enabled to maintain the internal temperature for an extended period of time without an outside electrical power is described. The cooling unit uses a combination of a battery (or one or more battery backs) and one or more phase change materials (“PCM”). In addition, the cooling unit uses one or more airpaths to force cooled air over a group of PCM to maintain the PCM for the event when an external electrical power is discontinued and the power from the battery pack is also depleted. The forced air through one of more airpaths may be always used or only when the cooling unit is operated by only the battery power.

### BACKGROUND

The present disclosure relates to a cooling unit, including but not limited to, a refrigerator, a freezer or a refrigerator and freezer combination. A cooling unit has been in use for decades to keep food fresh and cold. One of the drawbacks of a cooling unit is it relies on electricity. When the electricity is cutoff, the cooling unit fails to work and the food is spoiled. Food spoils especially quickly during transportation if the power supply is cutoff. Even when the cooling unit is disconnected for a short period of time to be transferred from one truck to another truck or be briefly stored to be loaded onto a truck or a cart. The problem of food soilage is exasperated when there is electrical power outage and even the standing cooling unit may not maintain a desired temperature for an extended period of time.

Accordingly, there has been a long felt need for a cooling unit that is able to maintain the internal temperature of the cooling unit at a desired level for a long period of time without continuous external electrical power. The disclosure presented herein is directed to solve these problems and satisfy the long-felt need.

### SUMMARY

The disclosure presented is to provide a cooling unit that is able to maintain the internal temperature for an extended period of time without an outside electrical power. The cooling unit uses a combination of a battery (or one or more battery backs) and one or more phase change materials (“PCM” or “phase change materials”). In addition, the cooling unit uses one or more airpaths to force cooled air over a group of PCM to maintain the PCM for the event when an external electrical power is discontinued and the power from the battery pack is also depleted. The forced air through one of more airpaths may be always used or only when the cooling unit is operated by only the battery power.

The cooling unit has an inner chamber. The inner chamber has a top side, a front side, a right side, a left side, a rear side and a bottom side. The cabinet has one or more refrigeration compartments as a part of the inner chamber and one or more mechanical compartments. Conventionally, one refrigeration compartment may be used as a refrigeration section and another refrigeration compartment may be used as a freezer section, but the number of the refrigeration compartment is subject to design choice. The one or more mechanical compartments house a battery (or a group of batteries or a battery pack) and a refrigeration unit with a coolant.

The cooling unit also has one or more phase change materials installed on one or more of the top side, the front side, the right side, the left side, the rear side or the bottom side. It is preferred to have the PCM on the rear side, if only one side is used to have the PCM; however, any or all of the other sides may also have PCM installed on it.

The refrigeration unit cools the inner chamber and the one or more phase change materials. It is preferred that the refrigeration unit cools the PCM first, then the inner chamber. It is a design choice to have more than one cooling chambers.

The battery is charged when an outside electricity is supplied to the cooling unit so that the batter can be used to power the refrigeration unit or as a backup power source when the outside electricity is discontinued. As the one or more phase change materials are always kept at low temperature, PCM help maintaining a predetermined temperature of the inner chamber all times, especially when the outside power source is disconnected or interrupted and when the battery is depleted.

The refrigeration unit uses the coolant passing through a cooling loop. Although it is not necessary that the cooling loop is attached to the one or more phase change materials to cool the one or more phase change materials, it is preferred so that PCM is effectively cooled. As the PCM is always cooled when the cooling loop is directly attached to the PCM, when there is electricity supplied, either by an external source of by the battery, temperature of the one or more phase change materials are maintained at lower temperature than the predetermined temperature of the inner chamber. It is a design choice to have more than one cooling loops so that one cooling loop is assigned to each set of PCM or one or more cooling loop is assigned to one or more inner chambers.

The cooling unit uses one or more blow fans that circulate air inside the inner chamber. The one or more blow fans may circulate air inside the inner chamber by directly blowing the air into the one or more refrigeration compartments or circulate air inside the inner chamber by first blowing the air onto the one or more phase change materials and then flow into the one or more refrigeration compartments.

To guide airflow over the PCM, the cabinet may have one or more separating panels mounted front of the one or more phase change materials, such that the one or more separating panels do not completely cover the one or more of the top side, the front side, the right side, the left side, the rear side or the bottom side. The one or more separating panels mounted front of the one or more phase change materials form one or more airpath in between the separating panel and the PCM. When the one or more or all of the blow fans are directed to blow into the airpath, then the air is forced over the PCM first and then let out into the refrigeration compartment.

An airpath may be formed in between the rear-separating panel and the PCM mounted on the rear side, in between the right-separating panel and the PCM mounted on the right side, and/or in between the left-separating panel and the PCM mounted on the left side. In addition, an airpath may be formed also in between the top-separating panel and the PCM mounted on the top side, in between the bottom-separating panel and the PCM mounted on the bottom side and in between the front-separating panel and the PCM mounted on the front side. The airflow may be designed to flow from the blow fans first to any one of the airpath thus formed. Also, the airflow may be directed from the blow fans to any sequence of the airpaths formed. For example, first through the airpath on the rear side, then through the airpath on the bottom side, then through the airpath on the left side and the right side. Also, it is optional to have the fan draw out air from the airpath, especially from the airpath on the rear side so the airflow is reverse of what is described.

Moreover, it is designers choice to form airpaths with no PCM mounted on one or more sides, especially on the front side which is often used as a door. Moreover, the cabinet may have a bottom-separating panel mounted on the bottom side. The bottom-separating panel does not have to completely cover the entirety of the bottom side, so that the bottom-separating panel mounted on the bottom side form a bottom airpath through which the air blown from the one or more blow fans flows through. In this configuration, it would be a design choice to mount the PCM on the bottom side or just have an airpath without the PCM.

The cooling unit also has a base unit attached below the bottom side. The base unit has a plurality of openings so that a pair of forks from a forklift may be inserted for easy lifting and transportation.

Although the present invention is briefly summarized, a better understanding of the invention can be obtained by the following drawings, detailed description and appended claims.

### BRIEF DESCRIPTION OF THE DRAWINGS

These and other features, aspects and advantages of the present invention will become better understood with reference to the accompanying drawings, wherein:

FIG. 1 is an open view of the cooling unit with the right side and the front side removed to show the inner chamber;

FIG. 2 is another open view of the cooling unit with the right side and the front side removed to show the inner chamber, showing the rear panel covering the rear side with PCM;

FIG. 3 is a cut-away view from the top of the cooling unit showing the mechanical compartment with the refrigeration unit and battery;

FIG. 4 is a cut-away view showing the front side, the right side and the rear side;

FIG. 5 is a cut-away view showing the PCM mounted on the left side and the rear side;

FIG. 6 is a cut-away view showing the PCM mounted on the right side and the rear side;

FIG. 7 is an open view of the cooling unit with the right side and the front side removed to show the left side covered with the left separating panel with air vents for the air to flow in or out;

FIG. 8A shows the simplified airflow of FIG. 7;

FIG. 8B shows the simplified airflow of FIG. 7 in reverse;

FIG. 9 is an open view of the cooling unit showing the airflow over the PCM, first airflow passes through the rear airpath, then through the bottom airpath and then through the refrigeration compartment;

FIG. 10 is an open view of the cooling unit showing the airflow over the PCM, first airflow passes through the refrigeration compartment, then through the bottom airpath and then through the rear airpath;

FIG. 11 is an open view of the cooling unit showing the airflow from the bottom airpath then through the refrigeration compartment;

FIG. 12 is an open view of the cooling unit showing the airflow first to the refrigeration compartment and then through the bottom airpath;

FIG. 13 is a view of the refrigeration system showing the blow fan, the refrigeration unit and the cooling loop; and

FIG. 14 is a forklift having a pair of forks.

### DETAILED DESCRIPTION EMBODIMENTS

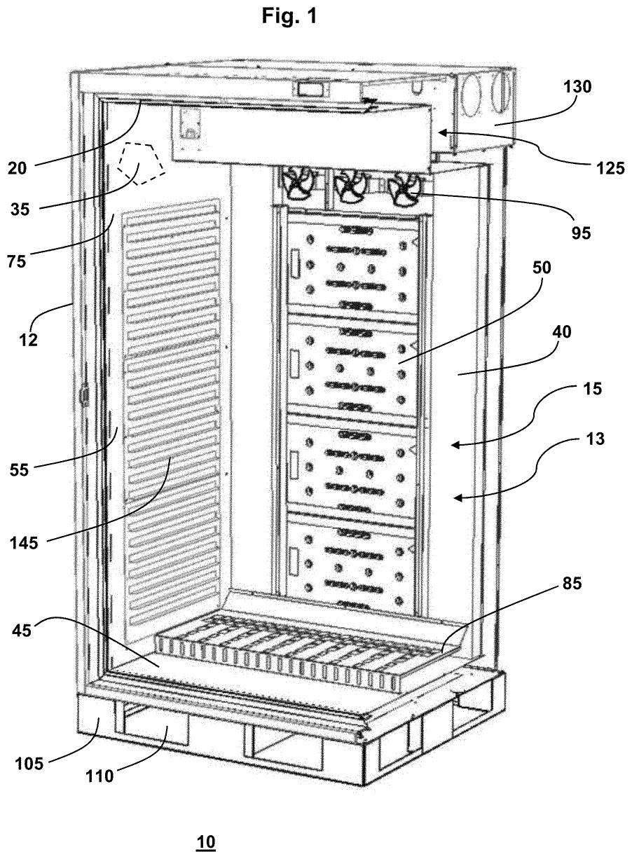

FIG. 1 shows a cooling unit 10 with a cabinet 12 having an inner chamber 15. Although a single inner chamber 15 is shown, a multiple inner chambers may be formed; for example, one refrigeration compartment and another freezer compartment. FIG. 1 shows a refrigeration compartment

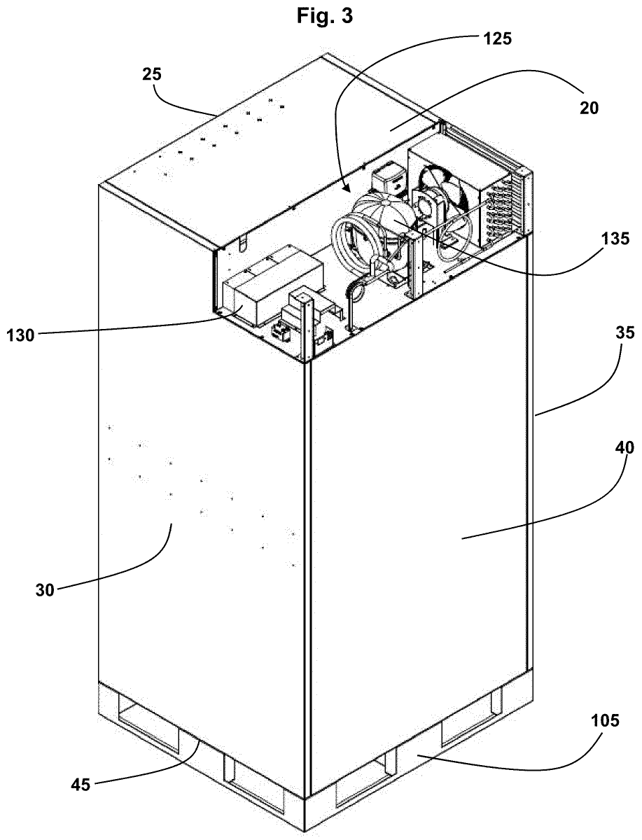

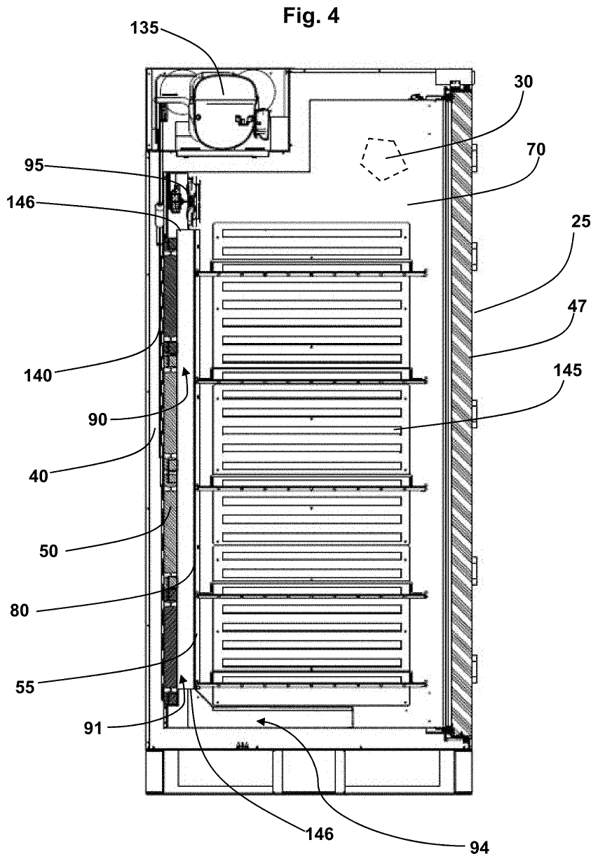

The inner chamber 15 has a top side 20, a front side 25 (shown in FIG. 4), a right side 30 (shown in FIGS. 3-6), a left side 35 (left side is below the left-separating panel 75, the left side is shown under the left-separating panel 75; the dotted line shows an imaginary opening on the left-separating panel 75), a rear side 40 and a bottom side 45. The right side 30 and the front side 25 are removed to show the inner chamber 15. The front side 25 is used as a door 47 (shown in FIG. 4), but either the left side 35 or the right side 30 may be substituted to be designed as the door 47.

The cooling unit 10 also has one or more phase change materials (“PCM”) 50 installed on one or more of the top side 20, the front side 25, the right side 30, the left side 35, the rear side 40 or the bottom side 45. It is preferred to have the PCM on the rear side 40, if only one side is used to have the PCM; however, any or all of the other sides may also have PCM installed on it. In FIG. 1, the rear side 40 has a plurality of PCM 50 mounted on it. The left side 35 also has PCM 50 mounted on it, but in FIG. 1, shows a separating panel 55 on the left side 35 over the PMC 50 mounted on the left side 35.

It is a design choice to have one or more separating panels 55 to cover or mounted front of the one or more of the tip side 20, the front side 25, the right side 30, the left side 35, the rear side 40 and the bottom side 45. When one or more separating panels 55 cover their respective sides and their respective sides have PCM mounted on them, the one or more separating panels 55 do not completely cover the one or more of the top side 20, the front side 25, the right side 30, the left side 35, the rear side 40 or the bottom side 45 so that air blown over the PCM 50 may escape. Although not all separating panels 55 are shown on FIG. 1, a separating panel 55 mounted on the top side 20 is top-separating panel (not shown), a separating panel 55 mounted on the front side is front-separating panel (not shown), a separating panel 55 mounted on the right side 30 is right-separating panel 70 (shown in Fig.), a separating panel 55 mounted on the left side 35 is left-separating panel 75, a separating panel 55 mounted on the real side 40 is rear-separating panel 80 (shown in Fig.), and a separating panel 55 mounted on the bottom side is bottom-separating panel (85).

The one or more separating panels 55 mounted front of the one or more phase change materials 50 form one or more airpath 90 (shown in FIG. 4) in between the separating panel 55 and the respective side (20, 25, 30, 35, 40 or 45) or in between the separating panel 55 and the respective PCM 50 forming an airpath 90 (shown in FIG. 4.)

When the one or more or all of the blow fans 95 are directed to blow into the airpath 90, then the air is forced over the PCM 50 first and then let out into the refrigeration compartment 13.

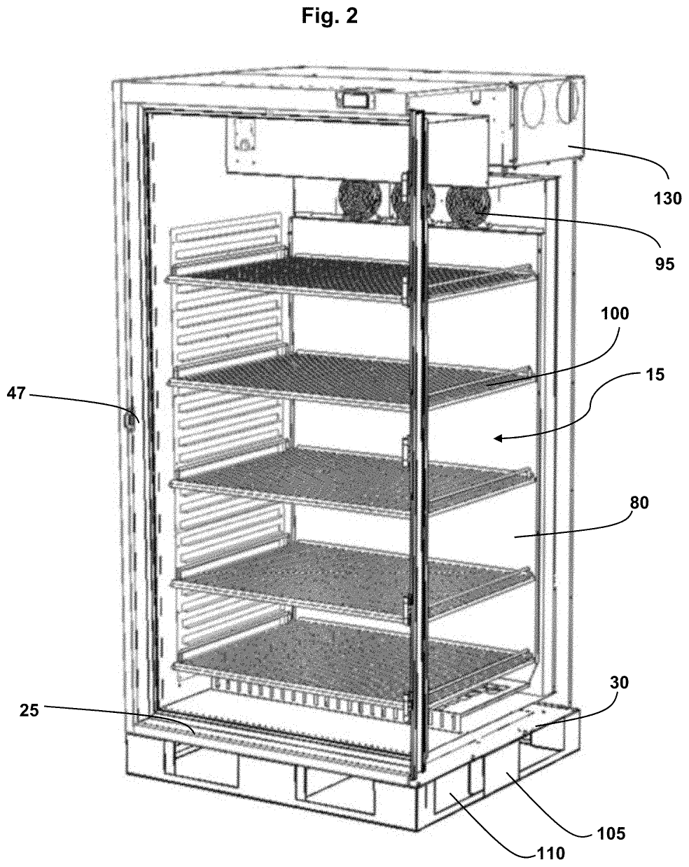

FIG. 2 is another open view of the cooling unit 10 with the right side 30 and the front side 25 removed to show the inner chamber 15, showing the rear-separating panel 80 covering the rear side 40 with PCM 50. FIG. 2 also shows a plurality of shelves in the inner chamber. In addition, FIG. 2 shows the cooling unit 10 having a base unit 105 attached below the bottom side 45. The base unit 105 has a plurality of openings 110 so that a pair of forks 115 from a forklift 120 may be inserted for easy lifting and transportation of the cooling unit 10. FIG. 2 also shows a mechanical compartment 125 that houses a battery 130.

FIG. 3 is a cut-away view from the top of the cooling unit 10 showing the mechanical compartment 125 with the refrigeration unit 135 and battery 130. The refrigeration unit 135 uses a coolant to cool the inner chamber 15 and the one or more phase change materials 50. It is preferred that the refrigeration unit 135 cools the PCM 50 first, then the inner chamber 15.

The battery 130 (or a group of batteries or a battery pack) is charged when an outside electricity is supplied to the cooling unit 10 so that the batter 130 can be used to power the refrigeration unit 135 or as a backup power source when the outside electricity is discontinued. As the one or more phase change materials 50 are always kept at low temperature, PCM 50 help maintaining a predetermined temperature of the inner chamber 15 all the time, especially when the outside power source is disconnected or interrupted and when the battery 130 is depleted.

FIG. 4 is a cut-away view showing the front side 25, the right side 30 (right side 30 is below the right-separating panel 70, the right side 30 is shown under the left-separating panel 70; the dotted line shows an imaginary opening on the right-separating panel 70) and the rear side 40. The refrigeration unit 135 uses the coolant passing through a cooling loop 140 (also shown in FIG. 10). Although it is not necessary that the cooling loop 140 is attached to the one or more phase change materials 50 to cool the one or more phase change materials 50 as show in FIG. 4, it is preferred so that PCM 50 is effectively cooled directly by the cooling loop 140. When there is electricity supplied, either by an external source of by the battery 130, because the PCM 50 is always cooled when the cooling loop 140 is directly attached to the PCM 50, the temperature of the one or more phase change materials 50 are maintained at lower temperature than the predetermined temperature of the inner chamber 15.

The cooling unit 10 uses one or more blow fans 95 that circulate air inside the inner chamber 15. The one or more blow fans 95 may circulate air inside the inner chamber 15 by directly blowing the air into the one or more refrigeration compartments 13 or circulate air inside the inner chamber 15 by first blowing the air onto and over the one or more phase change materials 50 and then flow into the one or more refrigeration compartments 13.

To guide airflow over the PCM 50, the cabinet may have one or more separating panels 55 mounted front of the one or more phase change materials 50, such that the one or more separating panels 55 do not completely cover the one or more of the top side 20, the front side 25, the right side 30, the left side 35, the rear side 40 or the bottom side 45. The one or more separating panels 55 mounted front of the one or more phase change materials 50 form one or more airpath 90 in between the separating panel 55 and the PCM 50 or in between the separating panel 55 and the respective side (20, 25, 30, 35, 40, 45). When the one or more or all of the blow fans 95 are directed to blow into the airpath 90, a rear airpath 91 in this Fig., then the air is forced over the PCM 55 first and then let out into the refrigeration compartment 13. It is a design choice to have one or more or all of the blow fans 95 are directed to blow into the airpath 90, but it is preferred to have at least one blow fan 95 is directed to blow into the airpath 90 and at least one blow fan 95 is directed to blow into the inside chamber 15.

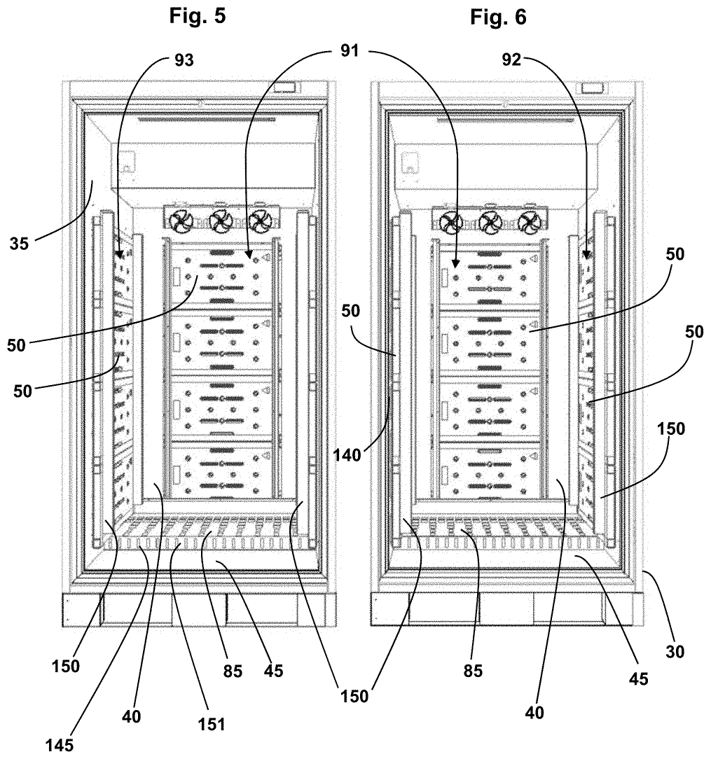

AS shown in FIG. 4, the rear airpath 91 is formed in between the rear-separating panel 80 and the PCM 50 mounted on the rear side 40. As design may require, a right airpath (shown in FIG. 6) may be formed in between the right-separating panel 70 and the PCM 50 mounted on the right side 30, and/or a left airpath 93 (shown in FIG. 5) may be formed in between the left-separating panel 75 and the PCM 50 mounted on the left side 35. In addition, an airpath 90 may be formed also in between the top-separating panel 60 and the PCM 50 mounted on the top side 20. Also, a bottom airpath 94 may be formed in between the bottom-separating panel 85 and the PCM 50 mounted on the bottom side 45 and in between the front-separating panel 65 and the PCM 50 mounted on the front side 25. The bottom airpath 94 is shown connected to the rear airpath 91 so the airflow may be continuous between the bottom airpath 94 and the rear airpath 91.

The airflow 90 may be designed to flow from the blow fans 95 first to any one of the airpaths 90 thus formed. Also, the airflow may be directed from the blow fans 95 to any sequence of the airpaths 90 formed. For example, the air is blown first through the rear airpath 91 on the rear side 40, then through the bottom airpath 94 on the bottom side 45, then through the left airpath 93 on the left side 35 and the right airpath 92 on the right side 30. Also, it is optional to have the blow fan 95 to have reverse airflow direction to draw out air from the airpath 90, especially from the rear airpath 91 on the rear side 40 so the airflow is reverse of what is described.

Moreover, it is designers choice to form airpaths 90 with no PCM 50 mounted on one or more sides (20, 25, 30, 35, 40, 45), especially on the front side 25 which is often used as a door 47. Moreover, the cabinet 12 may have a bottom-separating panel 85 mounted on the bottom side 45. The bottom-separating panel 85 does not have to completely cover the entirety of the bottom side 45, so that the bottom-separating panel 85 mounted on the bottom side 45 to form a bottom airpath 94 through which the air blown from the one or more blow fans 95 flows through. In this configuration, it would be a design choice to mount the PCM 50 on the bottom side 45 or just have the bottom airpath 94 without the PCM 50; or any one of the airpaths 90 to not have any PCM 50 mounted in it.

FIG. 4 also shows the right-separating panel 70 over the right side 30. The right-separating panel 70 does not completely cover the right side 30. In this configuration, the right-separating panel 70 has a plurality of air vents 145 so the air in the right airpath 92 may escape into the refrigeration compartment 13. A different embodiment may have the right-separating panel 70 fully cover the right side 30, but with the air vents 145 on the right-separating panel 70 to allow the air to escape through the air vents so that the right side 30 is not completely covered by the right-separating panel 70 with the right side exposed via the air vents 145.

Another embodiment may have the right-separating panel 70, not having any air vents 145, fully covering the right side 30 except at the ends 146 to have one or more airpaths 90 to its adjacent airpaths 90 of the adjacent sides, such as the rear side 40, the bottom side 45 and/or the top side 20, so that the airpaths 90 is continuous from the blow fans 95 to the refrigeration compartment 13. It is noted that the flow of air through one or more airpaths 90 of one or more sides (20, 25, 30, 35, 40, 45) may be interconnected in any combination to fit the design requirement of the cooling unit 10.

FIGS. 5 & 6 show cut-away views, showing the PCM 50 mounted on the left side 35, the right side 30 and the rear side 40. In FIGS. 5 & 6, although not shown, when the left-separating panel 75, the right-separating panel 70 and the rear-separating panel 80 cover the respective PCM 50, then the left airpath 93, the right airpath 92 and the rear airpath 91 are formed.

As shown, mounted on the left side 35, the right side 30 and the rear side 40 are a plurality of posts 150 that securely attach the left-separating panel 75, the right-separating panel 70 and the rear-separating panel 80. The posts 150 elevates each of the separating panels 55 off the PCM 50, forming the airpaths 90, so that air may flow over the PCM 50 through the airpaths 90.

FIGS. 5 & 6 do not show the top separating panel or the PCM 50 mounted on the top side 20. An embodiment may or may not have the PCM 50 mounted on the bottom side 45, because whether any of the sides (20, 25, 30, 35, 40 45) having PCM 50 is a design choice to fit the cooling requirement of the cooling unit 10.

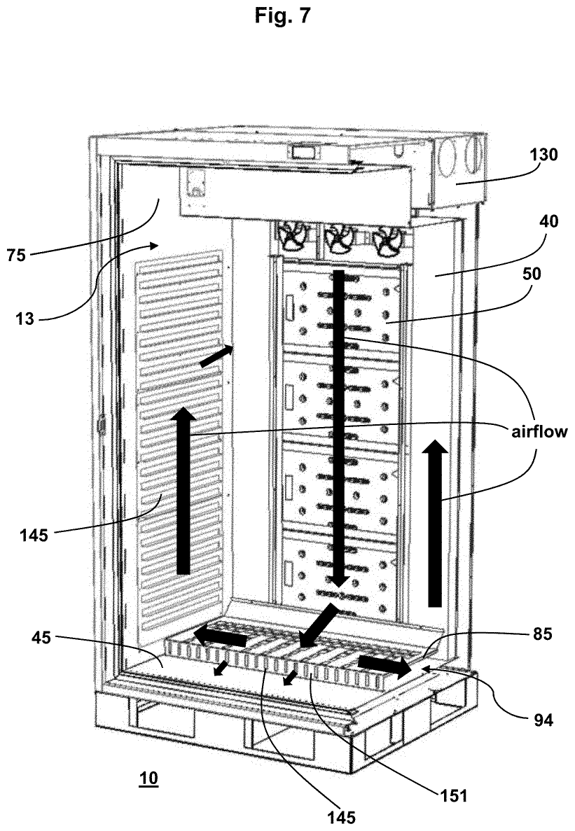

FIG. 7 is an open view of the cooling unit 10 with the right side 30 and the front side 25 removed to show the left side 35 covered with the left separating panel 75 with air vents 145 for the air to flow in or out. In this configuration, as shown by the airflow arrows, the air is blown over the PMC 50 mounted on the rear side 40 through the rear airpath 91 in between the rear-separating panel 80 and the rear side 40; the rear-separating panel is removed to better show the airpath. The airflow then moved down into the bottom airpath 94 in between the bottom-separating panel 85 and the bottom side 45. The airflow then moves into both the left airpath 93 (shown in FIG. 5) in between the left-separating panel 75 and the left side 35 and the right airpath 92 (shown in FIG. 6) in between the right-separating panel 70 and the right side 30. The airflow then, having moved through the left airpath 93 and the right airpath 92, exits through the air vents 145 out to the refrigeration compartment 13.

As an alternate design, the bottom-separating wall is separated by the bottom-separating posts 151 that has air vents 145 allowing some air to escape to the refrigeration compartment 13. The air vents 145 may be placed anywhere along the airpaths 90 (91, 92, 93, 94) to regulate the amount of air exited into the refrigeration compartment 13 to match the cooling requirement. FIG. 8A shows the simplified airflow of FIG. 7 for reference. FIG. 8B shows the simplified airflow of FIG. 7 in reverse.

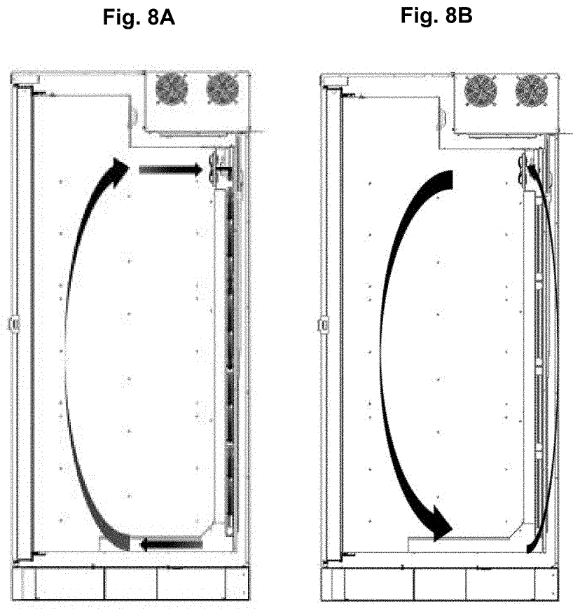

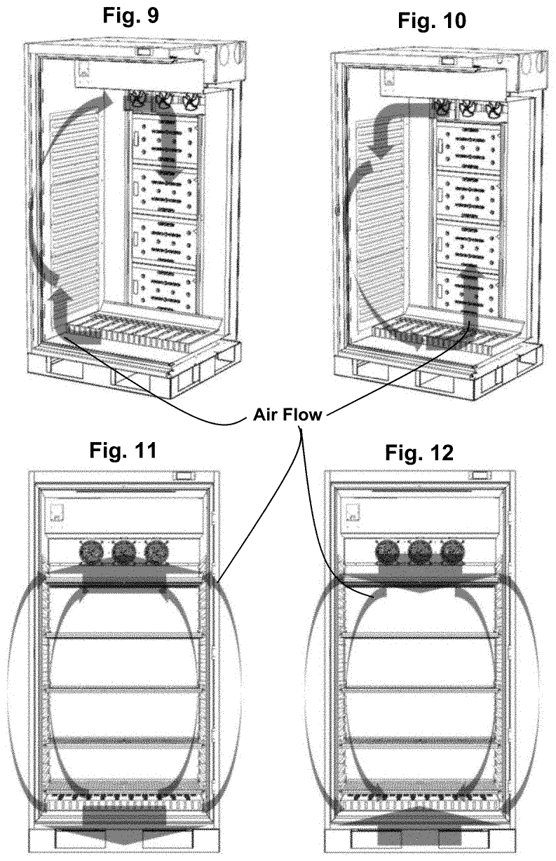

FIG. 9 is an open view of the cooling unit 10 showing the airflow over the PCM 50, first airflow passes through the rear airpath 91, then through the bottom airpath 94 and then through the refrigeration compartment 13;

FIG. 10 is an open view of the cooling unit 10 showing the airflow over the PCM 50, first airflow passes through the refrigeration compartment 13, then through the bottom airpath 94 and then through the rear airpath 91;

FIG. 11 is an open view of the cooling unit 10 showing the airflow from the bottom airpath 94 then through the refrigeration compartment 13.

FIG. 12 is an open view of the cooling unit 10 showing the airflow first to the refrigeration compartment 13 and then through the bottom airpath 94.

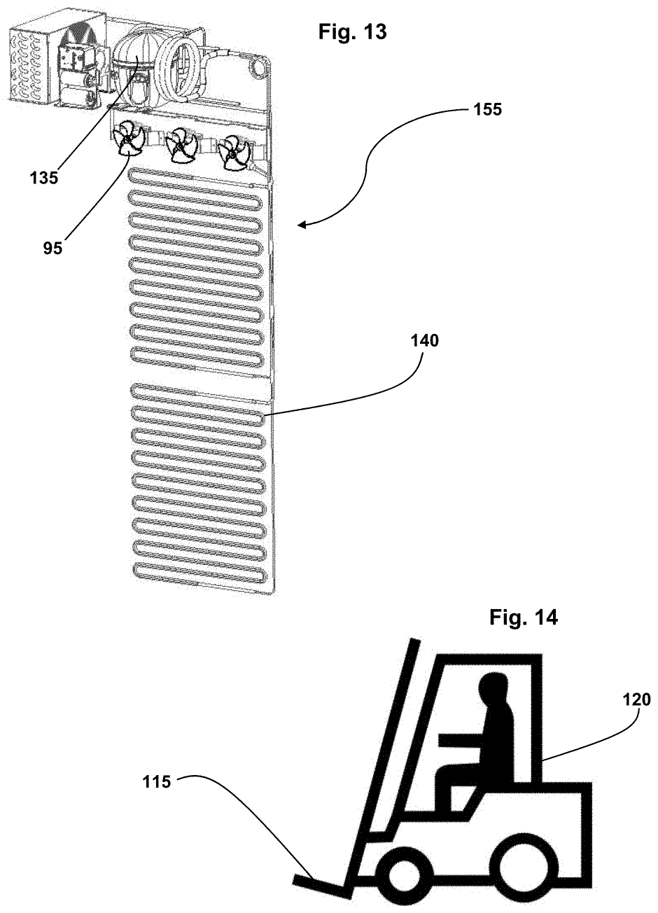

FIG. 13 is a view of the refrigeration system 155 showing the blow fan 95, the refrigeration unit 135 and the cooling loop 140. The cooling loop 140 may be directly attached to the PCM 50 to effectively cool PCM. The refrigeration system 155 may be designed to have a plurality of the cooling loops 140, one cooling loop for each side (20, 25, 30, 35, 40, 45) with PCM 50 mounted on it. It is a design choice to have more than one cooling loops 140 so that one cooling loop is assigned to each set of PCM 50 or one or more cooling loop 140 is assigned to one or more inner chambers 15.

FIG. 14 is a forklift 120 having a pair of forks 115. The pair of forks 115 may be inserted into the base unit 105 having a plurality of openings 110 so that the pair of forks 115 are used for easy lifting and transportation of the cooling unit 10.

While the preferred embodiment has been shown and described with reference to additional embodiments thereof, it will be appreciated by those skilled in the art that variations in form, detail, compositions and operation may be made without departing from the spirit and scope of the disclosure as defined by the accompanying claims.

What is claimed is:

1. A cooling unit comprising,
a cabinet with an inner chamber, wherein the inner chamber has a top side, a front side, a right side, a left side, a rear side and a bottom side;
the cabinet has one or more refrigeration compartments as a part of the inner chamber and one or more mechanical compartments, wherein the one or more mechanical compartments has a battery and a refrigeration unit with a coolant;
one or more phase change materials installed on one or more of the top side, the front side, the right side, the left side, the rear side or the bottom side, wherein the refrigeration unit cools the inner chamber and the one or more phase change materials; and
wherein the battery is charged when an outside electricity is supplied to the cooling unit so that the batter can be used to power the refrigeration unit when the outside electricity is discontinued; and
wherein the one or more phase change materials helps maintaining a predetermined temperature of the inner chamber.

2. The cooling unit of claim 1 wherein the coolant passes through a cooling loop attached to the one or more phase change materials to cool the one or more phase change materials.

3. The cooling unit of claim 1 wherein temperature of the one or more phase change materials are maintained at lower temperature than the predetermined temperature of the inner chamber.

4. The cooling unit of claim 1 further comprising one or more blow fans that circulate air inside the inner chamber by blowing the air over the one or more phase change materials.

5. The cooling unit of claim 4 wherein the cabinet further comprises one or more separating panels mounted front of the one or more phase change materials, wherein the one or more separating panels do not completely cover the one or more of the top side, the front side, the right side, the left side, the rear side or the bottom side on which the one or more phase change materials are attached so that each of the separating panels mounted front of the respective one or more phase change materials form a airpath through which the air blown from the one or more blow fans flows through.

6. The cooling unit of claim 4 further comprising a base unit attached below the bottom side wherein the base unit has a plurality of openings so that a pair of forks from a forklift may be inserted for easy lifting.

7. The cooling unit of claim 2 further comprising a base unit attached below the bottom side wherein the base unit has a plurality of openings so that a pair of forks from a forklift may be inserted for easy lifting.

8. The cooling unit of claim 2 further comprising one or more blow fans that circulate air inside the inner chamber by blowing the air over the one or more phase change materials.

9. The cooling unit of claim 8 wherein the cabinet further comprises one or more separating panels mounted front of the one or more phase change materials, wherein the one or more separating panels do not completely cover the one or more of the top side, the front side, the right side, the left side, the rear side or the bottom side on which the one or more phase change materials are attached to so that each of the separating panels mounted front of the respective one or more phase change materials form a airpath through which the air blown from the one or more blow fans flows through.

10. The cooling unit of claim 9 further comprising a base unit attached below the bottom side wherein the base unit has a plurality of openings so that a pair of forks from a forklift may be inserted for easy lifting.

11. The cooling unit of claim 4 wherein the cabinet further comprises a rear-separating panel mounted front of the phase change materials on the rear side, wherein rear-separating panel does not completely cover the rear side with the phase change materials are attached, so that the rear-separating panel mounted front of the phase change materials on the rear side form a rear airpath through which the air blown from the one or more blow fans flows through.

12. The cooling unit of claim 6 wherein the cabinet further comprises a rear-separating panel mounted front of the phase change materials on the rear side, wherein rear-separating panel does not completely cover the rear side with the phase change materials, so that the rear-separating panel mounted front of the phase change materials on the rear side form a rear airpath through which the air blown from the one or more blow fans flows through.

13. The cooling unit of claim 11 wherein the cabinet further comprises a left-separating panel mounted front of the phase change materials on the left side, wherein left-separating panel does not completely cover the left side with the phase change materials, so that the left-separating panel mounted front of the phase change materials on the left side form a left airpath through which the air blown from the one or more blow fans flows through.

14. The cooling unit of claim 13 wherein the cabinet further comprises a right-separating panel mounted front of the phase change materials on the right side, wherein right-separating panel does not completely cover the right side with the phase change materials, so that the right-separating panel mounted front of the phase change materials on the right side form a right airpath through which the air blown from the one or more blow fans flows through.

15. The cooling unit of claim 14 wherein the cabinet further comprises a bottom-separating panel mounted on the bottom side, wherein bottom-separating panel does not completely cover the bottom side, so that the bottom-separating panel mounted on the bottom side form a bottom airpath through which the air blown from the one or more blow fans flows through.

16. The cooling unit of claim 15 wherein the air blown from the one or more blow fans flows through the rear airpath first and then through the bottom airpath.

17. The cooling unit of claim 13 wherein the cabinet further comprises a bottom-separating panel mounted on the bottom side, wherein bottom-separating panel does not completely cover the bottom side, so that the bottom-separating panel mounted on the bottom side form a bottom airpath through which the air blown from the one or more blow fans flows through.

18. The cooling unit of claim 3 further comprising one or more blow fans that circulate air inside the inner chamber by blowing the air over the one or more phase change materials.

19. The cooling unit of claim 3 wherein the coolant passes through a cooling loop attached to the one or more phase change materials to cool the one or more phase change materials.

20. The cooling unit of claim 19 further comprising one or more blow fans that circulate air inside the inner chamber by blowing the air over the one or more phase change materials.
